(19) United States
(12) Patent Application Publication
(10) Pub. No.: US 2018/0310399 A1
(43) Pub. Date: Oct. 25, 2018

(54) MICROELECTRONIC DEVICES WITH EMBEDDED SUBSTRATE CAVITIES FOR DEVICE TO DEVICE COMMUNICATIONS

(71) Applicant: Intel Corporation, Santa Clara, CA (US)

(72) Inventors: Vijay K. NAIR, Mesa, AZ (US); Sasha N. OSTER, Chandler, AZ (US); Adel A. ELSHERBINI, Chandler, AZ (US); Telesphor KAMGAING, Chandler, AZ (US); Feras EID, Chandler, AZ (US)

(21) Appl. No.: 15/771,833

(22) PCT Filed: Dec. 21, 2015
(86) PCT No.: PCT/US2015/067184

§ 371 Date: Apr. 27, 2018

(51) Int. Cl. H05K 1/02; H01P 3/12; H01P 5/107; H05K 3/46

(52) U.S. Cl. CPC H05K 1/0243; H01P 3/121; H05K 2201/09618; H05K 3/4697; H05K 2201/037; H01P 5/107

(57) ABSTRACT

Embodiments of the invention include a waveguide structure that includes a lower member, at least one sidewall member coupled to the lower member, and an upper member. The lower member, the at least one sidewall member, and the upper member include at least one conductive layer to form a cavity in a substrate for allowing communications between devices that are coupled or attached to the substrate.

### FIELD OF THE INVENTION

Embodiments of the present invention relate generally to the manufacture of semiconductor devices. In particular, embodiments of the present invention relate to microelectronic devices having embedded substrate cavities for device to device communications.

### BACKGROUND OF THE INVENTION

Current server and client applications (i.e., central processing unit (CPU) applications) require a very high data rate between CPUs for multiple CPU systems and between CPUs and other mother board components (e.g. memory, non-volatile storage). A conventional approach for providing this high data rate is through a CPU socket or package solder bumps. However, due to the limited data rate through either option, a large number of socket pins or solder bumps are needed to provide the required data rate which leads to increased socket and package sizes resulting in increased cost and package and mother board complexity. In addition transmission of data at very high speed through copper lines that couple the CPUs on a mother board is very lossy due to surface roughness of the copper lines. These lines are also subject to cross talk interferences and spurious noise pickup.

### BRIEF DESCRIPTION OF THE DRAWINGS

FIG. 1 illustrates a view of a microelectronic device 100 having an embedded cavity within a substrate or printed circuit board according to an embodiment of the invention.

FIG. 2 illustrates a view of a microelectronic device 200 having an embedded cavity within a substrate or printed circuit board according to an embodiment of the invention.

FIG. 3A illustrates a side view of a substrate (or PCB) having an embedded cavity (or waveguide structure) according to an embodiment of the invention.

FIG. 3B illustrates a top view of a substrate (or PCB) having an embedded cavity (or waveguide structure) according to an embodiment of the invention.

FIG. 4A illustrates a side view of a substrate (or PCB) having an embedded cavity (or waveguide structure) according to an embodiment of the invention.

FIG. 4B illustrates a top view of a substrate (or PCB) having an embedded cavity (or waveguide structure) according to an embodiment of the invention.

FIG. 5 illustrates a view of a microelectronic device 500 having an embedded cavity within a substrate or printed circuit board according to an embodiment of the invention.

FIG. 6 illustrates a view of a microelectronic device 600 having an embedded cavity within a substrate or printed circuit board according to an embodiment of the invention.

FIGS. 7A-7D illustrate a process for manufacturing a substrate (or PCB) having an embedded cavity (or waveguide structure), according to an embodiment of the invention.

FIG. 8 illustrates a substrate 800 having a waveguide and exciting structure in accordance with one embodiment.

FIG. 9 illustrates a simulated loss of a waveguide for a frequency band in accordance with one embodiment.

FIG. 10 illustrates a cross-sectional view of an embedded cavity (or waveguide) of a substrate according to another embodiment of the invention.

FIG. 11 illustrates a cross-sectional view of an embedded cavity (or waveguide) of a substrate according to another embodiment of the invention.

FIG. 12 illustrates a computing device 1200 in accordance with one embodiment of the invention.

### DETAILED DESCRIPTION OF THE INVENTION

Described herein microelectronic devices having embedded substrate cavities for device to device communications. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order to not obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

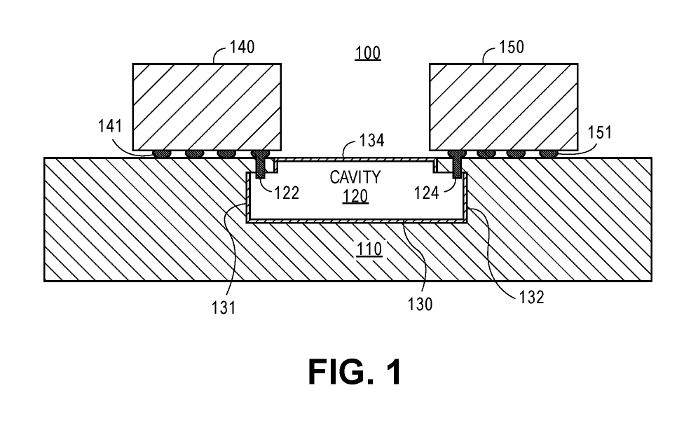

Referring now to FIG. 1, a view of a microelectronic device 100 having an embedded cavity within a substrate or printed circuit board is shown, according to an embodiment of the invention. In one example, the microelectronic device 100 includes multiple devices 140 and 150 (e.g., die, package, chip, CPU, etc.) that are coupled or attached to a substrate 110 (or printed circuit board 110) with solder balls 141 and 151. An enclosed cavity 120 (or waveguide structure) is formed within the substrate 110 (or printed circuit board 110). The enclosed cavity 120 (or waveguide structure) allows communications between the devices 140 and 150 at a high data speed. The cavity 120 (or waveguide structure) includes a lower member 130, sidewalls 131-132, and an upper member 134. In one example, the lower member 130, sidewalls 131-132, and the upper member 134 include conductive layers (e.g., metal layers). Exciting structures 122 and 124 transmit signals from the devices 140 and 150, respectively. The enclosed cavity can be air filled or low loss dielectric waveguides.

A conventional approach uses metal lines in a mother board for transmitting data between CPUs. However, the metal lines are very lossy due to surface roughness of the metal lines. These lines are also subject to cross talk interferences and spurious noise pickup. Another approach uses wireless interconnects to provide very high data rate through wireless chip to chip packages. However, this approach requires the use of antennas on the mother board or platform which although reconfigurable, may require higher power to account for the low directivity typically provided by these relatively small package antennas. Since these antennas are placed in a noisy environment in open air between chips or packages, the antennas are subject to noise pick up, multipath variations, and interference from nearby metal objects.

The present design provides a better and more efficient way to transmit data between devices using enclosed embedded cavities (or waveguide structures) in a substrate. In one example, the embedded cavities (or waveguide structures) can be implemented using milled or etched out grooves (or any other means for forming cavities) in a substrate and these embedded cavities (or waveguide structures) can be excited using simple structures in a device or substrate. A traditional waveguide can be formed on a substrate but this requires the use of relatively high cost low loss substrates. Air filled or low loss dielectric waveguide structures enable a much lower loss compared to antennas and can also be implemented using standard substrate or PCB fabrication techniques.

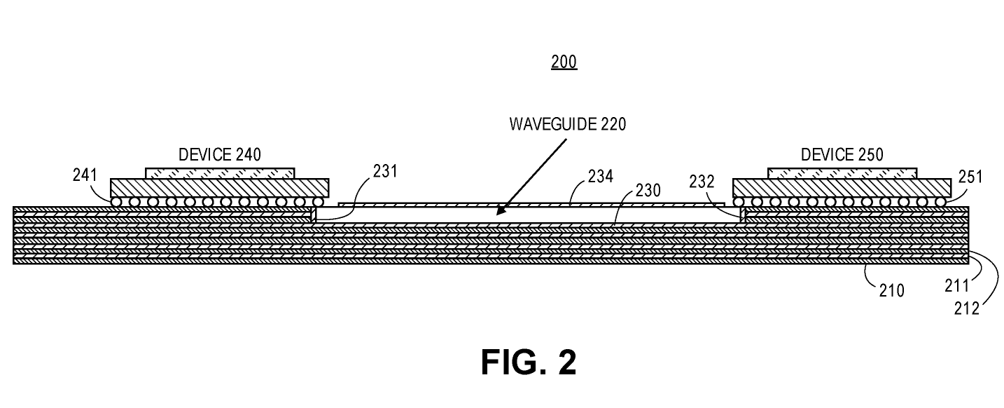

FIG. 2 illustrates a view of a microelectronic device 200 having an embedded cavity within a substrate or printed circuit board according to an embodiment of the invention. In one example, the microelectronic device 200 includes multiple devices 240 and 250 (e.g., die, package, chip, CPU, etc.) that are coupled or attached to a substrate 210 (or printed circuit board 110) with solder balls 241 and 251. An enclosed cavity 220 (or waveguide structure 220) is formed within the substrate 210 (or printed circuit board 210). The enclosed cavity 220 (or waveguide structure) allows communications between the devices 240 and 250 at a high data speed. The cavity 220 (or waveguide structure) includes a lower member 230, sidewalls 231-232 (which can include additional sidewalls not shown in FIG. 2), and an upper member 234. In one example, the lower member 230, sidewalls 231-232, and the upper member 234 include conductive layers (e.g., metal layers). The enclosed cavity 220 (or waveguide structure) is a very controlled environment and provides shielding from external noises and radio frequency (RF) interference. Excitation structures can be integrated with the devices 240 and 250 or coupled to these devices 240 and 250. The enclosed cavity can be air filled or low loss dielectric waveguides.

The present design provides significantly higher data rates per socket pin or package bump in comparison to prior approaches such as copper interconnects, which can be used for lower frequency communications. The present design is also better than package integrated antennas because the present design has a significantly lower loss for point to point communications due to the enclosed cavities or waveguides guiding the radiation of the transmitting signals between two devices with minimal loss.

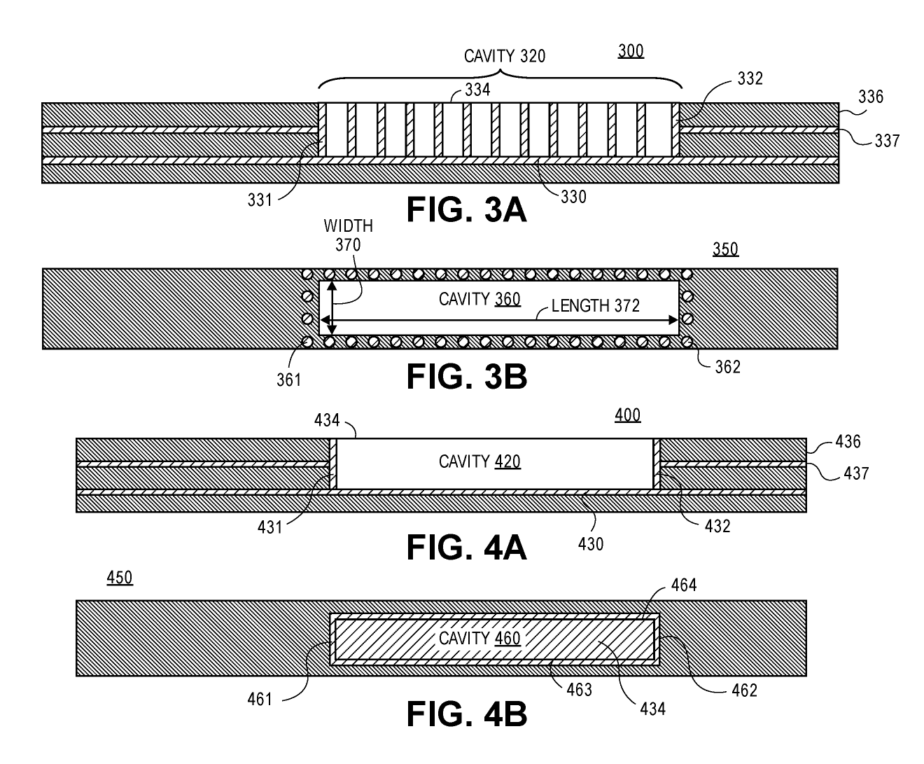

FIG. 3A illustrates a side view of a substrate (or PCB) having an embedded cavity (or waveguide structure), according to an embodiment of the invention. An enclosed cavity 320 (or waveguide structure 320) is formed within the substrate 300 (or printed circuit board 300). The enclosed cavity 320 (or waveguide structure) allows communications between devices that are coupled to or in proximity to opposite sides of the cavity at a high data speed. The cavity 320 (or waveguide structure) includes a lower member 330, sidewall members 331-332 (which can include additional sidewall members shown or not shown in FIG. 3A), and an upper member 334. In one example, the lower member 330, sidewall members 331-332, and the upper member 334 include conductive layers (e.g., metal layers). The enclosed cavity 320 (or waveguide structure) is a very controlled environment and provides shielding from external noises and radio frequency (RF) interference. Excitation structures can be integrated with the communicating devices or integrated with the substrate and coupled to these devices. The enclosed cavity can be air filled or low loss dielectric waveguides. The substrate can include layers of insulating dielectric layers 336 and conductive layers 337.

FIG. 3B illustrates a top view of a substrate (or PCB) having an embedded cavity (or waveguide structure), according to an embodiment of the invention. An enclosed cavity 360 (or waveguide structure 360) is formed within the substrate 350 (or printed circuit board 350). The enclosed cavity can be similar or have similar features in comparison to the cavity 320. The enclosed cavity 360 (or waveguide structure) allows communications between devices that are coupled to opposite sides of the cavity at a high data speed. The cavity 360 (or waveguide structure) includes a lower member (e.g., not shown in FIG. 3B, lower member 330 in FIG. 3A), sidewall members 361-362 (which can include additional sidewall members shown or not shown in FIG. 3B), and an upper member (e.g., not shown in FIG. 3B, upper member 334 in FIG. 3A). The cavity 360 has a width 370 and a length 372. Excitation structures can be integrated with the communicating devices or integrated with the substrate and coupled to these devices. The enclosed cavity can be air filled or low loss dielectric waveguides. The substrate can include layers of insulating dielectric layers and conductive layers. In one example, the sidewall members (e.g., 331-332, 361-362) are formed with one or more levels of vias (e.g., 2 via levels, 3 via levels, etc.). The spacing of the vias depends on a desired frequency or frequency band for transmitting data between the communicating devices. In another example, the vias are closely spaced to each other to form a solid or approximately solid wall of vias. The vias can be electrically coupled to each other through the ground planes (e.g., lower member 330 or 430, upper member 334 or 434)

FIG. 4A illustrates a side view of a substrate (or PCB) having an embedded cavity (or waveguide structure), according to an embodiment of the invention. An enclosed cavity 420 (or waveguide structure 420) is formed within the substrate 400 (or printed circuit board 400). The enclosed cavity 420 (or waveguide structure) allows communications between devices that are coupled to or in proximity to opposite sides of the cavity at a high data speed. The cavity 420 (or waveguide structure) includes a lower member 430, sidewall members 431-432 (which can include additional sidewall members not shown in FIG. 4A), and an upper member 434. In one example, the lower member 430, sidewalls 431-432, and the upper member 434 include conductive layers (e.g., metal layers). Excitation structures can be integrated with the communicating devices or integrated with the substrate and coupled to these devices. The enclosed cavity can be air filled or low loss dielectric waveguides. The substrate can include layers of insulating dielectric layers 436 and conductive layers 437.

FIG. 4B illustrates a top view of a substrate (or PCB) having an embedded cavity (or waveguide structure), according to an embodiment of the invention. An enclosed cavity 460 (or waveguide structure 460) is formed within the substrate 450 (or printed circuit board 450). The enclosed cavity 460 can be similar or have similar features in comparison to the cavity 420. The enclosed cavity 460 (or waveguide structure) allows communications between devices that are coupled to or in proximity to opposite sides of the cavity at a high data speed. The cavity 460 (or waveguide structure) includes a lower member (e.g., not shown in FIG. 4B, lower member 430 in FIG. 3A), sidewall members 461-464, and an upper member 434. In one example, the lower member, sidewall members 461-464, and the upper member 434 include conductive layers (e.g., metal layers). Excitation structures can be integrated with the communicating devices or integrated with the substrate and coupled to these devices. The enclosed cavity can be air filled or low loss dielectric waveguides. The substrate can include layers of insulating dielectric layers and conductive layers. In one example, the sidewall members (e.g., 331-332, 361-362) are formed with one or more levels of vias (e.g., 2 via levels, 3 via levels, etc.). The sidewall members can be formed (e.g., plating waveguide sidewalls) to enclose all sides and surfaces of the cavity with one or more conductive layers.

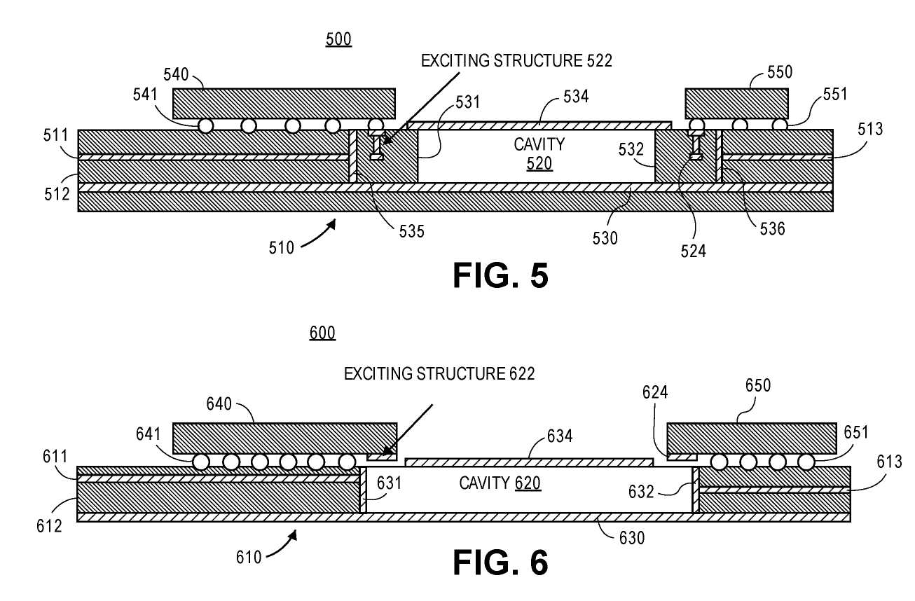

FIG. 5 illustrates a view of a microelectronic device 500 having an embedded cavity within a substrate or printed circuit board according to an embodiment of the invention. In one example, the microelectronic device 500 includes multiple devices 540 and 550 (e.g., die, package, chip, CPU, etc.) that are coupled or attached to a substrate 510 (or printed circuit board 110) with solder balls 541 and 551. An enclosed cavity 520 (or waveguide structure) is formed within the substrate 510 (or printed circuit board 510). The enclosed cavity 520 (or waveguide structure) allows communications between the devices 540 and 550 at a high data speed with high frequency transmissions. In one example, the frequency is at least 100 GHz. The cavity 520 (or waveguide structure) includes a lower member 530, sidewalls 531-532, and an upper member 534. In one example, the lower member 530, the upper member 534, and layers 511 and 513 include conductive layers (e.g., metal layers). Exciting structures 522 and 524 transmit signals from the devices 540 and 550, respectively. These structures 522 and 524 are adjacent to members 535 and 536 (e.g., conductive members, reflective members, ground plane), respectively. In one example, the members 535 and 536 are spaced approximately 200-300 microns from a respective exciting structure. The enclosed cavity can be air filled or low loss dielectric waveguides. In one example, the exciting structures are formed with one or more levels of vias.

FIG. 6 illustrates a view of a microelectronic device 600 having an embedded cavity within a substrate or printed circuit board according to an embodiment of the invention. In one example, the microelectronic device 600 includes multiple devices 640 and 650 (e.g., die, package, chip, CPU, etc.) that are coupled or attached to a substrate 610 (or printed circuit board 610) with solder balls 641 and 651. An enclosed cavity 620 (or waveguide structure) is formed within the substrate 610 (or printed circuit board 610). The enclosed cavity 620 (or waveguide structure) allows communications between the devices 640 and 650 at a high data speed with high frequency transmissions. In one example, the frequency is at least 100 GHz. In another example, the frequency is at least 30 GHz. The cavity 620 (or waveguide structure) includes a lower member 630, sidewalls 631-632, and an upper member 634. In one example, the lower member 630, the upper member 634, and layers 611 and 613 include conductive layers (e.g., metal layers). Exciting structures 622 and 624 transmit RF signals from the devices 640 and 650, respectively into the cavity 620 through electromagnetic coupling. The enclosed cavity can be air filled or low loss dielectric waveguides. In one example, the exciting structures are formed with one or more levels of vias.

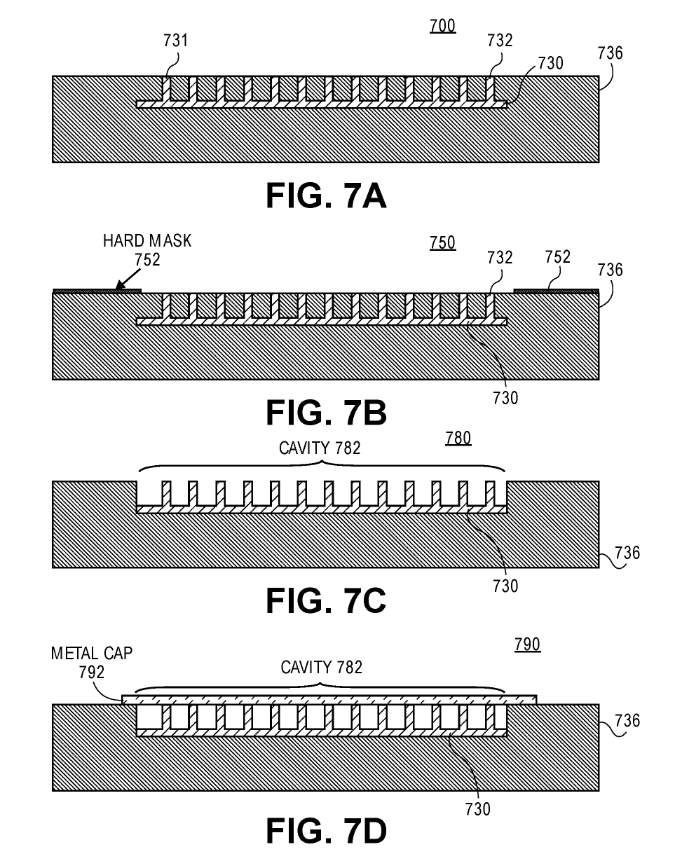

FIGS. 7A-7D illustrate a process for manufacturing a substrate (or PCB) having an embedded cavity (or waveguide structure) according to an embodiment of the invention. In principle, the illustrated layering may be varied. For example, additional layers may be interspersed, containing dielectrics, functional layers, or other components for other microelectronic devices present on the common substrate. Likewise, certain of the illustrated layers (for example layers underlying the waveguide components) may or may not be present in a device that is nonetheless in accordance with embodiments.

A substrate 700 (or printed circuit board 700) is formed with one or more insulating dielectric layers 736, a conductive layer 730 that forms a bottom of a waveguide, and one or more via levels to form sidewall members 731-732 of the waveguide. The substrate may contain copper or other materials including, without limitation, glass or organic material.

In FIG. 7B, a hard mask layer 752 (e.g., electroless copper) is applied to a substrate 750 and patterned using photolithography to open an area for creating a cavity or waveguide. The substrate 750 includes similar layers as illustrated in FIG. 7A and additionally includes the hard mask layer 752.

In FIG. 7C, in one example, a dielectric layer 736 is etched or removed (e.g., plasma etch, reactive ion etch, etc.) in an area opened by the hard mask layer 752 to form a cavity 782. In another example, a dielectric layer 736 is removed with laser drilling to form a cavity 782 in which case no hard mask layer 752 is needed. The substrate 780 includes similar layers as illustrated in FIG. 7B and additionally includes the formation of the cavity 782.

In FIG. 7D, in one example, a metal plate or cap 792 is placed on a substrate 790 to cap or enclose the cavity 782. The metal plate can be attached using epoxy or an adhesive film. The substrate 790 includes similar layers as illustrated in FIG. 7C and additionally includes the addition of the metal plate 792.

In an alternative process flow, a metal layer with a mesh can be placed or formed on the substrate 790 before the cavity is created to replace the cap 792 which in the previous process flow is placed after the cavity is created. In one example, dimensions of the mesh openings are sufficiently large to etch portions of the substrate in order to create the cavity while sufficiently small enough electrically to be solid or approximately solid for a propagating field.

In another alternative process flow, a waveguide is fabricated separately and then placed or integrated with a cavity formed in a substrate.

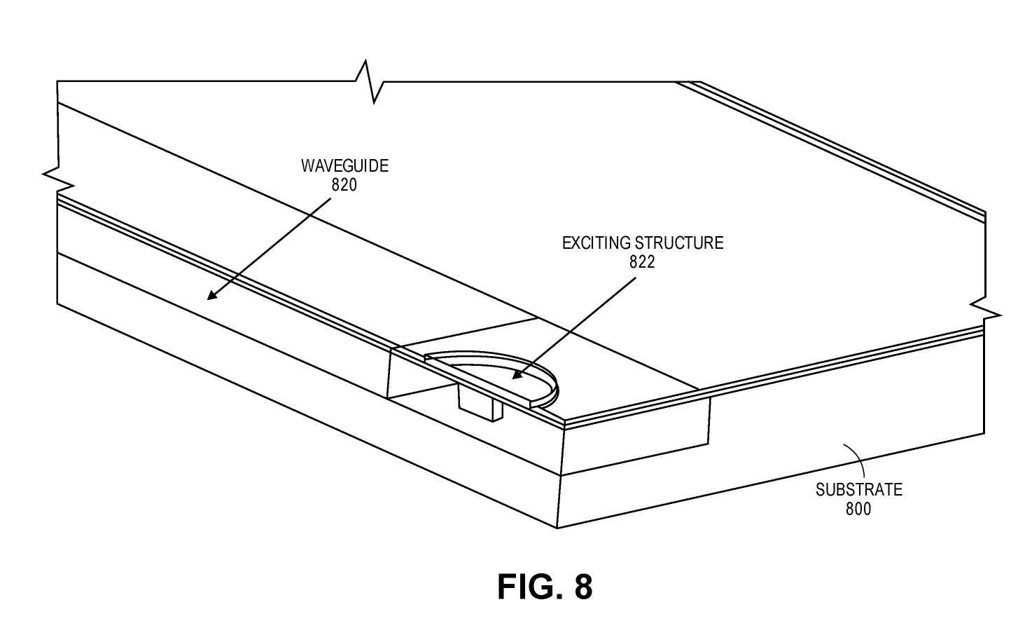

FIG. 8 illustrates a substrate 800 having a waveguide and exciting structure in accordance with one embodiment. The waveguide 820 and exciting structure 822 are simulated to determine a simulated transmission loss. In one example, the waveguide 820 and exciting structure 822 include similar features in comparison to the cavity 120 and exciting structure 122, respectively, of FIG. 1.

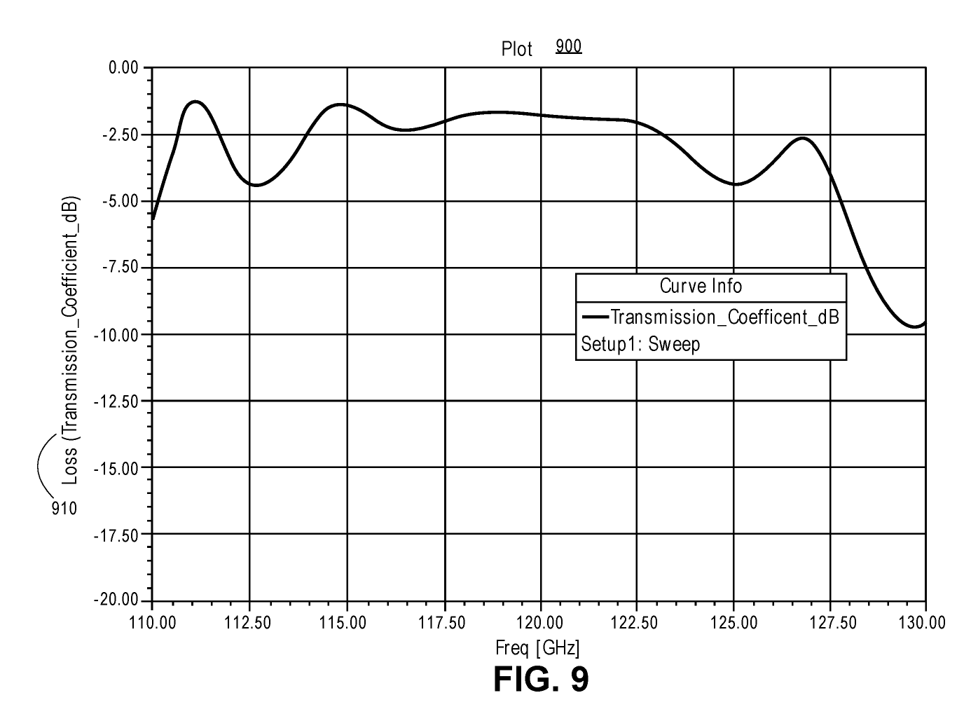

FIG. 9 illustrates a simulated loss of a waveguide for a frequency band in accordance with one embodiment. The transmission loss of the waveguide 820 (e.g., cavity 120) and exciting structure 822 (e.g., exciting structure 122, 124) was simulated and the result is shown in an xy (x axis, y axis) plot of loss 910 (e.g., transmission_coefficient_dB) versus a frequency sweep from 110 GHz to 130 GHz. The simulated loss is less than 2 dB for a portion of the frequency sweep as illustrated in FIG. 9. The simulated loss includes a transition loss from a package or device to a junction of the waveguide to exciting structure and also a waveguide loss during transmission of the signals along a y axis of the waveguide.

For comparison, a fully filled waveguide (not air filled) shows more than a 12 dB loss for a same length of waveguide. Losses and bandwidth can be further improved using optimized feed structures.

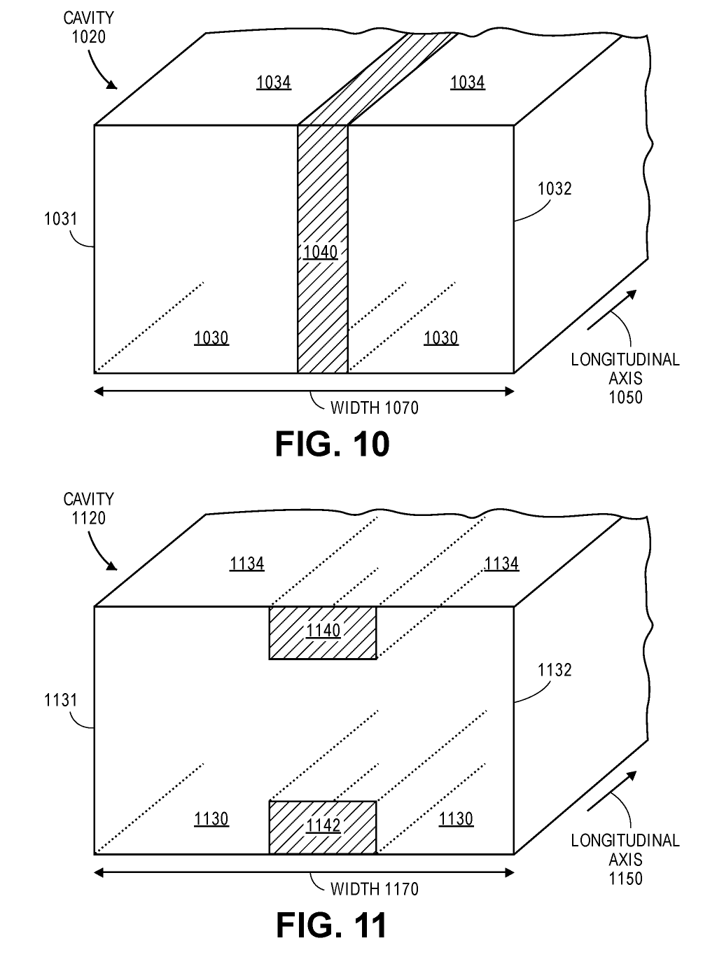

FIG. 10 illustrates a cross-sectional view of an embedded cavity (or waveguide) of a substrate according to another embodiment of the invention. An enclosed cavity 1020 (or waveguide structure 1020) is formed within a substrate (or printed circuit board) in accordance with embodiments of the present design. The enclosed cavity 1020 (or waveguide) allows communications between devices that are coupled to or in proximity to opposite sides of the cavity at a high data speed. The cavity 1020 (or waveguide) includes a conductive lower member 1030, at least partially conductive sidewall members 1031-1032 (which can include additional sidewall members shown or not shown in FIG. 10), an insulating dielectric dividing member 1040, and a conductive upper member 1034. The cavity 1020 has a width 1070. The enclosed cavity 1020 (or waveguide) provides a controlled environment and provides shielding from external noises and radio frequency (RF) interference. The enclosed cavity 1020 including the dividing member 1040 extend along a longitudinal axis 1050. Excitation structures can be integrated with the communicating devices or integrated with the substrate and coupled to these devices. The enclosed cavity can be air filled or low loss dielectric waveguides. In this example, the dividing member 1040 divides the cavity into a first cavity to the left of the dividing member and a second cavity to the right of the dividing member in FIG. 10. The dividing member can be positioned at any location within the cavity 1020 or have any type of shape for dividing the cavity.

FIG. 11 illustrates a cross-sectional view of an embedded cavity (or waveguide) of a substrate according to another embodiment of the invention. An enclosed cavity 1120 (or waveguide structure 1120) is formed within a substrate (or printed circuit board) in accordance with embodiments of the present design. The enclosed cavity 1120 (or waveguide) allows communications between devices that are coupled to or in proximity to opposite sides of the cavity at a high data speed. The cavity 1120 (or waveguide) includes a conductive lower member 1130, at least partially conductive sidewall members 1131-1132 (which can include additional sidewall members shown or not shown in FIG. 11), a conductive upper first ridge 1140, a conductive lower ridge 1142, and a conductive upper member 1134. The cavity 1120 has a width 1170. In one example, at least one of the ridges 1140 and 1142 is included in the cavity. The enclosed cavity 1120 (or waveguide) provides a controlled environment and provides shielding from external noises and radio frequency (RF) interference. The enclosed cavity 1120 including the ridges 1140 and 1142 extend along a longitudinal axis 1150. Excitation structures can be integrated with the communicating devices or integrated with the substrate and coupled to these devices. The enclosed cavity can be air filled or low loss dielectric waveguides.

The cavity can have any shape (e.g., rectangular, circular, etc.) and have any type of dividing member or ridges in accordance with embodiments of the present invention. The cavity can have a width that is approximately a same order of magnitude as a wavelength of a guided wave. In one example, the cavity has a width that is greater than or equal to half of a breaking wavelength of a guided wave.

For high frequency communications (e.g., 100-130 GHz, 25 GHz to 1 THz), a cavity has a width of approximately 2 mm.

It will be appreciated that, in a system on a chip embodiment, the die may include a processor, memory, communications circuitry and the like. Though a single die is illustrated, there may be none, one or several dies included in the same region of the microelectronic device.

In one embodiment, the microelectronic device may be a crystalline substrate formed using a bulk silicon or a silicon-on-insulator substructure. In other implementations, the microelectronic device may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the scope of the present invention.

The microelectronic device may be one of a plurality of microelectronic devices formed on a larger substrate, such as, for example, a wafer. In an embodiment, the microelectronic device may be a wafer level chip scale package (WLCSP). In certain embodiments, the microelectronic device may be singulated from the wafer subsequent to packaging operations, such as, for example, the formation of one or more sensing devices.

One or more contacts may be formed on a surface of the microelectronic device. The contacts may include one or more conductive layers. By way of example, the contacts may include barrier layers, organic surface protection (OSP) layers, metallic layers, or any combination thereof. The contacts may provide electrical connections to active device circuitry (not shown) within the die. Embodiments of the invention include one or more solder bumps or solder joints that are each electrically coupled to a contact. The solder bumps or solder joints may be electrically coupled to the contacts by one or more redistribution layers and conductive vias.

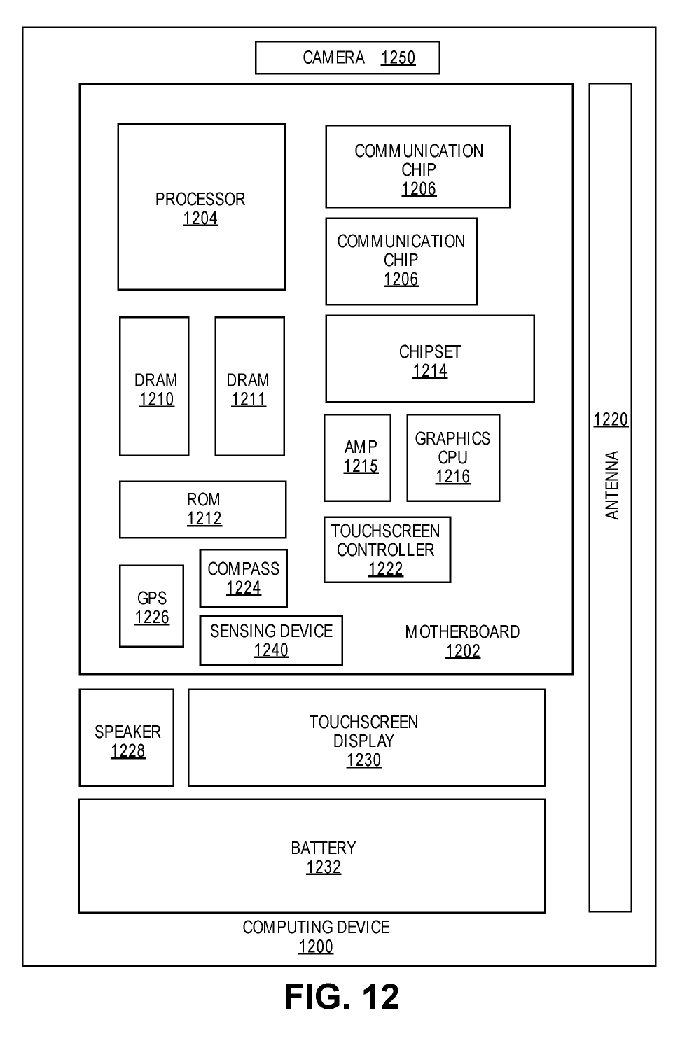

FIG. 12 illustrates a computing device 1200 in accordance with one embodiment of the invention. The computing device 1200 houses a board 1202. The board 1202 may include a number of components, including but not limited to a processor 1204 and at least one communication chip 1206. The processor 1204 is physically and electrically coupled to the board 1202. In some implementations the at least one communication chip 1206 is also physically and electrically coupled to the board 1202. In further implementations, the communication chip 1206 is part of the processor 1204.

Depending on its applications, computing device 1200 may include other components that may or may not be physically and electrically coupled to the board 1202. These other components include, but are not limited to, volatile memory (e.g., DRAM 1210, 1211), non-volatile memory (e.g., ROM 1212), flash memory, a graphics processor 1216, a digital signal processor, a crypto processor, a chipset 1214, an antenna 1220, a display, a touchscreen display 1230, a touchscreen controller 1222, a battery 1232, an audio codec, a video codec, a power amplifier 1215, a global positioning system (GPS) device 1226, a compass 1224, a sensing device 1240 (e.g., an accelerometer), a gyroscope, a speaker, a camera 1250, and a mass storage device (such as hard disk drive, compact disk (CD), digital versatile disk (DVD), and so forth).

The communication chip 1206 enables wireless communications for the transfer of data to and from the computing device 1200. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1206 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1200 may include a plurality of communication chips 1206. For instance, a first communication chip 1206 may be dedicated to shorter range wireless communications such as Wi-Fi, WiGig and Bluetooth and a second communication chip 1206 may be dedicated to longer range wireless communications such as GPS, EDGE, GPRS, CDMA, WiMAX, LTE, Ev-DO, 5G, and others.

The processor 1204 of the computing device 1200 includes an integrated circuit die packaged within the processor 1204. In some implementations of the invention, the integrated circuit die of the processor includes one or more devices, such as sensing devices in accordance with implementations of embodiments of the invention. The term “processor” may refer to any device or portion of a device that processes electronic data from registers and/or memory to transform that electronic data into other electronic data that may be stored in registers and/or memory.

The communication chip 1206 also includes an integrated circuit die packaged within the communication chip 1206. In accordance with another implementation of embodiments of the invention, the integrated circuit die of the communication chip includes one or more sensing devices.

The following examples pertain to further embodiments. Example 1 is a waveguide structure comprising a lower member, at least one sidewall member coupled to the lower member, and a upper member. The lower member, the at least one sidewall member, and the upper member include at least one conductive layer to form a cavity in a substrate for allowing communications between devices that are coupled or attached to the substrate.

In example 2, the subject matter of example 1 can optionally include the cavity that provides shielding from external noises and radio frequency (RF) interference.

In example 3, the subject matter of any of examples 1-2 can optionally further include at least one exciting structure to transmit communications from a first device to a second device.

In example 4, the subject matter of any of examples 1-2 can optionally have the cavity to receive communications from at least one exciting structure that is integrated with at least one of the first and second devices.

In example 5, the subject matter of any of examples 1-4 can optionally have the cavity be air filled for communications having a frequency of at least 100 GHz.

In example 6, the subject matter of any of examples 1-5 can optionally have the cavity be air filled for communications having a frequency of at least 30 GHz.

In example 7, the subject matter of any of examples 1-6 can optionally include the at least one sidewall member which includes a plurality of sidewall members that are spaced a threshold distance from each other based on a frequency of the communications.

In example 8, a microelectronic device includes at least two devices coupled or attached to a substrate, an enclosed cavity formed in the substrate, and at least two exciting structures coupled to the at least two devices. The at least two exciting structures transmit and receive communications between the at least two devices.

In example 9, the subject matter of example 8 can optionally include the enclosed cavity having a lower member, at least one sidewall member coupled to the lower member, and an upper member. The lower member, the at least one sidewall member, and the upper member to form the enclosed cavity in the substrate. The lower member, the at least one sidewall member, and the upper member may each include at least one conductive layer.

In example 10, the subject matter of any of examples 8-9 can optionally include the at least one sidewall member including a plurality of sidewall members that are spaced a threshold distance from each other based on a frequency of the communications.

In example 11, the subject matter of any of examples 8-10 can optionally include the enclosed cavity to provide shielding from external noises and radio frequency (RF) interference.

In example 12, the subject matter of any of examples 8-11 can optionally include the enclosed cavity being air filled for communications having a frequency of at least 30 GHz.

In example 13, the subject matter of any of examples 8-12 can optionally include the enclosed cavity having a rectangular shape. In another example, the enclosed cavity can have any shape.

In example 14, the subject matter of any of examples 8-13 can optionally include the lower member having a first ridge extending along a longitudinal axis of the enclosed cavity and the upper member having a second ridge extending along the longitudinal axis.

In example 15, the subject matter of any of examples 8-14 can optionally include the lower member, the at least one sidewall member, and the upper member having at least one conductive layer to form the enclosed cavity in the substrate.

In example 16, a method of manufacturing a substrate with a waveguide includes forming a substrate with one or more insulating dielectric layers, forming a conductive layer on the substrate with the conductive layer being a bottom of a waveguide, forming one or more via levels to form sidewall members of the waveguide, and removing a region of the substrate to create a cavity of waveguide.

In example 17, the subject matter of example 16 can optionally include removing the region of the substrate by etching or laser drilling a dielectric layer to form the cavity.

In example 18, the subject matter of any of examples 16-17 optionally further includes forming a metal plate on the substrate to cap or enclose the cavity.

In example 19, the subject matter of any of examples 16-18 optionally further includes forming a metal plate with a mesh on the substrate to cap or enclose the cavity.

In example 20, the subject matter of any of examples 16-19 optionally includes the cavity being air filled for communications having a frequency of at least 30 GHz.

1. A waveguide structure comprising:
a lower member;
at least one sidewall member coupled to the lower member; and
an upper member, wherein the lower member, the at least one sidewall member, and the upper member include at least conductive layer to form a cavity in a substrate for allowing communications between devices that are coupled or attached to the substrate.

2. The waveguide structure of claim 1, wherein the cavity provides shielding from external noises and radio frequency (RF) interference.

3. The waveguide structure of claim 1, further comprising:
at least one exciting structure to transmit communications from a first device to a second device.

4. The waveguide structure of claim 1, wherein the cavity to receive communications from at least one exciting structure that is integrated with at least one of the first and second devices.

5. The waveguide structure of claim 1, wherein the cavity is air filled for communications having a frequency of at least 100 GHz.

6. The waveguide structure of claim 1, wherein the cavity is air filled for communications having a frequency of at least 30 GHz.

7. The waveguide structure of claim 1, wherein the at least one sidewall member includes a plurality of sidewall members that are spaced a threshold distance from each other based on a frequency of the communications.

8. A microelectronic device comprising:
at least two devices coupled to a substrate;
an enclosed cavity formed in the substrate; and
at least two exciting structures coupled to the at least two devices, the at least two exciting structures for transmitting and receiving communications between the at least two devices.

9. The microelectronic device of claim 8, wherein the enclosed cavity comprises:
a lower member;
at least one sidewall member coupled to the lower member; and
an upper member, wherein the lower member, the at least one sidewall member, and the upper member to form the enclosed cavity in the substrate.

10. The microelectronic device of claim 9, wherein the at least one sidewall member includes a plurality of sidewall members that are spaced a threshold distance from each other based on a frequency of the communications.

11. The microelectronic device of claim 8, wherein the enclosed cavity provides shielding from external noises and radio frequency (RF) interference.

12. The microelectronic device of claim 8, wherein the enclosed cavity is air filled for communications having a frequency of at least 30 GHz.

13. The microelectronic device of claim 8, wherein the enclosed cavity has a rectangular shape.

14. The microelectronic device of claim 8 wherein the lower member includes a first ridge extending along a longitudinal axis of the enclosed cavity and the upper member includes a second ridge extending along the longitudinal axis.

15. The microelectronic device of claim 8, wherein the lower member, the at least one sidewall member, and the upper member include at least one conductive layer to form the enclosed cavity in the substrate.

16. A method of manufacturing a substrate with a waveguide, comprising:
forming a substrate with one or more insulating dielectric layers,
forming a conductive layer on the substrate with the conductive layer being a bottom of a waveguide;
forming one or more via levels to form sidewall members of the waveguide; and
removing a region of the substrate to create a cavity of waveguide.

17. The method of claim 16, wherein removing the region of the substrate comprises etching or laser drilling a dielectric layer to form the cavity.

18. The method of claim 16, further comprising:
forming a metal plate on the substrate to cap or enclose the cavity.

19. The method of claim 16, further comprising:
forming a metal plate with a mesh on the substrate to cap or enclose the cavity.

20. The method of claim 16, wherein the cavity is air filled for communications having a frequency of at least 30 GHz.
